(19) United States
(12) Patent Application Publication
(10) Pub. No.: US 2025/0194133 A1
(43) Pub. Date: Jun. 12, 2025

(54) SEMICONDUCTOR STRUCTURE HAVING LOW ON-RESISTANCE AND METHOD FOR MANUFACTURING THEREOF

(71) Applicant: TAIWAN SEMICONDUCTOR MANUFACTURING COMPANY LTD., HSINCHU (TW)

(72) Inventors: HSIN-CHIH CHIANG, HSINCHU CITY (TW); YU-HSUAN LIN, HSINCHU (TW); KUN-HUANG YU, HSINCHU COUNTY (TW); CHI-CHIH CHEN, YUNLIN COUNTY (TW); CHIH-WEN YAO, HSINCHU CITY (TW); CHIH-CHANG CHENG, HSINCHU CITY (TW); TSUNG-YI HUANG, HSINCHU COUNTY (TW); RUEY-HSIN LIU, HSINCHU CITY (TW); MING-TA LEI, HSIN-CHU CITY (TW)

(21) Appl. No.: 18/531,748

(22) Filed: Dec. 7, 2023

(51) Int. Cl. H01L 29/66; H01L 29/06; H01L 29/10; H01L 29/423; H01L 29/78

(52) U.S. Cl. CPC H10D 30/027; H10D 30/603; H10D 62/10; H10D 62/393; H10D 64/516

(57) ABSTRACT

A semiconductor structure is provided. The semiconductor structure includes a substrate, a plurality of well regions, a gate structure, a drain region, a source region, a circuit, and a voltage source. The gate structure includes a gate oxide over a first surface of the substrate and a gate electrode over the gate oxide. The gate oxide includes a first portion and a second portion connected with the first portion, wherein a thickness of the second portion is greater than that of the second portion. The voltage source is coupled to the drain region, configured to provide a first voltage to the drain region. The circuit is coupled to the gate structure, configured to provide a second voltage to the gate structure. A ratio of the first voltage to the second voltage is in a range from 2 to 4. Methods for manufacturing the semiconductor structure are also provided.

### BACKGROUND

Fabrication of a metal-oxide-semiconductor (MOS) integrated circuit involves numerous processing steps. A gate oxide is typically formed from silicon dioxide formed over a semiconductor substrate. For each MOS field effect transistor (MOSFET) being formed, a gate electrode is formed over the gate dielectric, and dopant impurities are then introduced into the semiconductor substrate to form source and drain regions.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a semiconductor structure according to some embodiment of the present disclosure.

FIG. 2 illustrates a cross-sectional view of a semiconductor structure according to some embodiment of the present disclosure.

FIGS. 3A to 31 illustrate cross-sectional views of manufacturing a semiconductor structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

The resistance value between the drain and source of a metal-oxide-semiconductor field-effect transistor (MOSFET) during operation (i.e., ON) is called the on-resistance (Ron). Generally, the smaller the on-resistance value is, the lower the power loss.

In other words, the on-resistance of a transistor refers to the resistance encountered by current flow when the transistor is in its “on” or conducting state. This typically occurs when sufficient voltage is applied to the transistor's terminals, allowing current to flow between the source terminal and the drain terminal for a field-effect transistor (FET) or between the collector and emitter terminals for a bipolar junction transistor (BJT). The on-resistance is susceptible to influence from the semiconductor material's properties, the transistor's dimensions, and the voltage applied to the gate. Low on-resistance is desirable in many applications because it leads to less voltage drop and power dissipation in the conducting state, which is important in power electronics and switching applications.

In some comparative embodiments of the present disclosure, a semiconductor structure may include a substrate, the substrate may be a P-type wafer typically used in the semiconductor manufacturing industry. There are various conventionally used P-type dopants may be employed to confer P-type characteristics to the substrate. The substrate, composed of a semiconductor material such as silicon, can be negatively biased using conventional techniques. In some comparative embodiments, there exists an N⁺ buried layer (NBL) formed within the substrate, with its top surface being coplanar with surface of the substrate. The NBL is preferably constituted by an N-type dopant that is a heavy atom and resistant to diffusion during subsequent high-temperature processes. In one embodiment, antimony (Sb) may be utilized as the N-type dopant impurity.

Conventional masking techniques, in conjunction with ion implantation or other methods, can introduce the N-type dopant impurity into the substrate to form the NBL, followed by the application of thermal drive-in techniques. Using such terminology, an N⁺ or P⁺ region like the NBL designates a highly doped region of N-type or P-type dopant impurities, typically with a dopant impurity concentration exceeding about 1×10¹⁴ to 1×10¹⁶ atoms/cm².

In some comparative embodiments, since a P-type epitaxial layer, to be later formed, will be a relatively lightly doped layer, an additional surface implant may be implemented After the NBL drive-in process to prevent adjacent NBL layers from punch-through and to enhance the high voltage breakdown voltage.

In some comparative embodiments, the P-type epitaxial layer is located over the NBL. In some comparative embodiments, the epitaxial deposition temperature may be 1200° C. but may range from 1050° C. to 1350° C. in other comparative embodiments. In some comparative embodiments, the P-type epitaxial layer may have a resistivity within a range from about 1 ohm-cm to about 100 ohm-cm. For example, the P-type epitaxial layer may include a thickness of 4.5 μm and a resistivity of 45 ohm-cm in one comparative embodiment, but other thicknesses may be used in other comparative embodiments. In another example, the thickness may range from 4 μm to 5 μm and the P-type epitaxial layer may include a resistivity within the range from 40 to 50 ohm-cm.

In some comparative embodiments, a plurality of differently doped regions are formed within the P-type epitaxial layer using typical patterning, ion implantation and drive-in techniques. The P-type epitaxial layer may have a P-well region, an N-well region, and a deep P-well region. The P-well region is above adjacent to the N-well region, and the deep P-well region, which has a relatively deep doping profile, is covered by the N-well region.

In some comparative embodiments, a gate structure is located over a surface of the substrate. The gate structure may include a gate oxide and a gate electrode over the gate oxide. In some comparative embodiments, the gate structure is laterally surrounded by gate sidewall spacer structure. In addition, a resist protective oxide (RPO) layer can be formed over the gate structure, the gate sidewall spacer structure, and the N-well region, along the profile of the gate structure, the gate sidewall spacer structure, and the substrate. The N-well region at the surface of the substrate is covered by the resistant protect oxide layer entirely, while only a N⁺ region for the landing of the drain contact is exposed from the resistant protect oxide layer.

In some comparative embodiments, the resist protective oxide layer is deposited within the areas where silicide layers are not intended to be formed (as an undesired silicide layer could lead to leakage current). Meanwhile, the resist protective oxide layer exposes the surfaces over the source, drain and gate electrode regions for the subsequent placement of contacts.

In an example of some comparative embodiments, the semiconductor structure with the resist protective oxide layer, a pitch of a source and a drain of the semiconductor structure is about 0.38 μm, an off-mode leakage at 5.5V_{d} is about 0.02 pA/μm, a breakdown voltage at 25 nA/μm is about 11.9 V, a linear-region drain current (I_{dlin}) is about 67.3 μA/μm, and an on-resistance is about 1.20 mΩ/mm².

In circuit design, the voltage applied to the bias connected to the gate structure can influence the gate voltage. As a result, the thickness of the gate oxide corresponds to the gate voltage value; for instance, if the gate voltage is 2.5V, the gate oxide thickness will be relatively thinner compared to the scenario where the gate voltage is 5V. In some comparative embodiments, where the gate voltage is lower than the drain voltage (e.g., 2.5V for the gate and 5V for the drain), it becomes necessary to increase the distance between the gate and the drain for voltage endurance. Furthermore, structures like the resist protective oxide layer can also be employed to augment voltage endurance.

On the other hand, in instances where the gate voltage is set at 2.5V, and the drain voltage is fixed at 5V, it is inappropriate to merely increase the gate oxide thickness to enhance gate voltage endurance. This is because utilizing a thicker gate oxide designed for a 5V scenario when the voltage is 2.5V would markedly diminish the performance of semiconductor structure. Furthermore, in situations with high drain voltage (e.g., 10V or higher), attempts have been made to integrate structures like shallow trench isolation (STI) between the gate and drain. However, this approach augments the path for current flow, resulting in a reduction in linear-region drain current and the degradation of parameters such as on-resistance. Therefore, in some embodiments of the present disclosure, when both the gate voltage and the drain voltage remain unchanged, the present disclosure provides an approach to optimize the on-resistance performance of the semiconductor structure without sacrificing or compromising the linear-region drain current or the source-to-drain pitch. Unlike the comparative embodiments, some embodiments of the present disclosure utilize a Resurf (Reduced Surface Electric Field) oxide over the N-well region to enhance the on-resistance performance of the semiconductor structure. Furthermore, the semiconductor structure in this disclosure not only exhibits a relatively low on-resistance but also allows for an increase in on-mode current (i.e., linear-region drain current) and a decrease in the source-to-drain pitch.

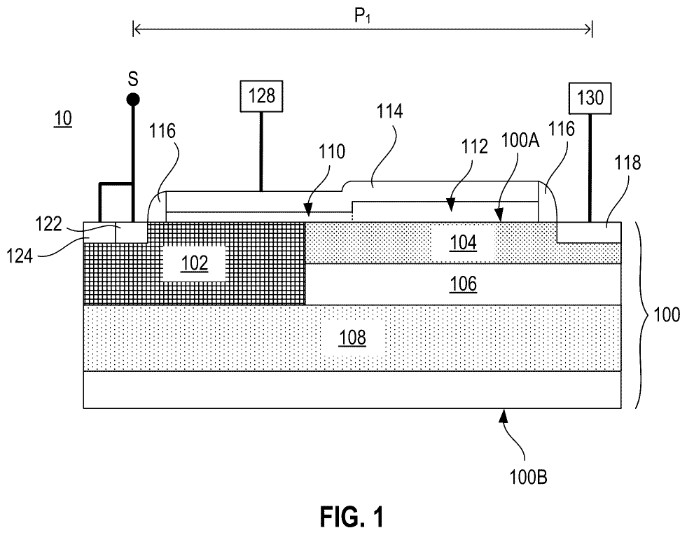

Referring to FIG. 1, in some embodiments, a semiconductor structure 10 may include a substrate 100, wherein the substrate 100 has a first surface 100A and a second surface 100B opposite to the first surface 100A. In some embodiments, the substrate 100 includes a first well region 102 having a first type dopant in proximity to the first surface 100A of the substrate 100, and a second well region 104 having a second type dopant in proximity to the first surface 100A of the substrate 100 and adjacent to the first well region 102. In some embodiments, the first type dopant can be a P-type dopant, which some examples of the P-type dopant includes boron (B), aluminum (Al), gallium (Ga) and indium (In). In some embodiments, the second type dopant can be an N-type dopant, which some examples of the N-type dopant includes phosphorus (P), antimony (Sb), and arsenic (As). Accordingly, in some embodiments, the substrate 100 may have a P-well (PW) region (i.e., the first well region 102) and an N-well (NW) region (i.e., the second well region 104) at the first surface thereof. In some embodiments, a deep P-well (DPW) region 106 is located below the second well region 104, and laterally adjacent to the first well region 102.

In some embodiment, the dopant impurity concentration of the first type dopant in the first well region 102 is in a range from about 1×10¹¹ atoms/cm² to about 9×10¹³ atoms/cm². In some embodiments, the dopant impurity concentration of the second type dopant in the second well region 104 is in a range from about 1×10¹¹ atoms/cm² to about 9×10¹³ atoms/cm². In some embodiments, the dopant impurity concentration of the P-type dopant in the deep P-well region 106 is in a range from about 1×10¹¹ atoms/cm² to about 9×10¹³ atoms/cm².

In some embodiments, the substrate 100 may be a P-type wafer, which may have a resistivity in a range from about 1 ohm-cm to about 100 ohm-cm. In some embodiments, the substrate 100 can be composed of a semiconductor material such as silicon. In some embodiments, other than the first well region 102 and the second well region 104, the substrate 100 further includes an N⁺ buried layer (NBL) 108 below the first well region 102 and the second well region 104. In some embodiments, the NBL 108 may include an N-type dopant. The purpose of the NBL 108 is typically to provide a highly conductive path within the semiconductor material, and often buried beneath the surface of the substrate. The NBL 108 may enhance the electrical characteristics of the semiconductor structure, such as reducing resistivity and enabling efficient electron transport. In some embodiments, the N-type dopant in the NBL 108 may have a dopant impurity concentration in a range from about 1×10¹⁴ to 1×10¹⁶ atoms/cm².

In some embodiments, the semiconductor structure 10 further includes a gate structure over the first surface 100A of the substrate 100. In a typical MOSEFT, the gate is utilized to control the conductivity of a channel between the source and the drain, and the operation of a MOSFET relies on the ability to control the flow of charge carriers (e.g., electrons or holes) in the channel beneath the gate. For instance, when a voltage is applied to the gate, the gate may create an electric field that either enhances or depletes the concentration of charge carriers in the channel, allowing or restricting the flow of current between the source and the drain. In some embodiments of the present disclosure, referring to FIG. 1, the gate structure includes a gate oxide 110 over the first surface 100A of the substrate 100 and covering a boundary of the first well region 102 and the second well region 104, a thickened gate oxide 112 laterally adjacent to the gate oxide 110 and over the second well region 104, and a gate electrode 114 over the gate oxide 110 and the thickened gate oxide 112.

The gate oxide 110 is a thin dielectric film at the bottom of the gate structure. Generally, the gate oxide 110 may serve as a vital insulating layer between the gate electrode 114 and the semiconductor material (e.g., the substrate 100). This insulator enables the controlled modulation of the channel beneath the gate structure, dictating the flow of charge carriers and thus the semiconductor structure (e.g., the MOSEFT) conductivity. When a voltage is applied to the gate structure, the electric field across the gate oxide may influence the distribution of charge carriers in the semiconductor structure, determining whether the channel becomes more conductive (on-state) or less conductive (off-state). In addition, the gate oxide 110 may also serve as a barrier to prevent unwanted leakage current between the gate electrode 114 and the semiconductor material (e.g., the substrate 100). In some embodiments, the material of the gate oxide 110 includes silicon dioxide (SiO₂). In some embodiments, a thickness of the gate oxide 110 is no greater than about 10 μm.

As previously mentioned, some embodiments of the present disclosure utilize the Resurf oxide over the N-well region to enhance the on-resistance performance of the semiconductor structure. That is, as shown in FIG. 1, the thickened gate oxide 112 laterally adjacent to the gate oxide 110 and over the second well region 104 (e.g., N-well region). In some embodiments, the thickness of the thickened gate oxide 112 is greater than the thickness of the gate oxide 110. In some embodiments, the thickness of the thickened gate oxide is in a range from about 10 nm to about 100 nm. In some embodiments, the material of the gate oxide 110 is identical to the material of the thickened gate oxide 112. On the other hand, since the gate oxide 110 is leveled with the thickened gate oxide 112, the thickened gate oxide 112 can be seen as a thicker extension of the gate oxide 110 horizontally towards the drain region. In other words, compared with the comparative embodiment, without covering the second well region 104 by the resist protective oxide layer, the present disclosure uses the thickened gate oxide 112 disposed over the second well region 104 at the first surface 100A of the substrate 100 not only ensured the voltage endurance needed of the semiconductor structure, but significantly optimize the on-resistance thereof.

As previously mentioned, in the example of the comparative embodiments, the semiconductor structure with the resist protective oxide layer may have an on-resistance as about 1.20 mΩ/mm². However, by using the thickened gate oxide 112 connected with the gate oxide 110 in the present embodiments, the on-resistance can be optimized to at about 0.97 mΩ/mm², which is equivalent to about 20% reduction in on-resistance.

In other aspects of the performance of the semiconductor structure 10, the semiconductor structure 10 with the thickened gate oxide 112 may have an off-mode leakage at 5.5 V_{d} is about 0.02 pA/μm, a breakdown voltage at 25 nA/μm is about 12.1 V, which is substantially similar to the example in the comparative embodiments. However, the semiconductor structure 10 with the thickened gate oxide 112 may have a linear-region drain current (I_{dlin}) is about 69.7 μA/μm, which means that the on-mode current can be substantially enhanced.

Furthermore, by using the thickened gate oxide 112, the distance between the gate structure and the drain region can be shortened, for instance, the pitch P₁ of the source and the drain of the semiconductor structure can be reduced from about 0.38 μm (i.e., the example previously described in the comparative embodiments) to about 0.32 μm. Therefore, not only the size of the semiconductor structure can be reduced, but the density of the semiconductor structure within a semiconductor device can thus be increased.

In some embodiments, the length of the gate oxide 110 projectively over the first well region 102 is in a range from about 0.03 μm to about 1 μm. In some embodiments, the length of the gate oxide 110 projectively over the second well region 104 is in a range from about 0.03 μm to about 1 μm. In some embodiments, the length of the thickened gate oxide 112 projectively over the second well region 104 is in a range from about 0.03 μm to about 1 μm. In some embodiments, the length of the gate oxide 110 projectively over the second well region 104 is shorter than the length of the gate oxide 110 projectively over the first well region 102. In some embodiments, the length of the gate oxide 110 projectively over the second well region 104 is shorter than the length of the thickened gate oxide 112 projectively over the second well region 104.

Since the length of the thickened gate oxide 112 projectively over the second well region 104 is related to the optimized of the performance of the on-resistance, in some embodiments, the length of the thickened gate oxide 112 projectively over the second well region 104 is determined based on calculation or simulation result to make the transistor structure having the on-resistance lower than about 1 mΩ/mm². In addition, because the length of the thickened gate oxide 112 projectively over the second well region 104 is related to the performance of the on-resistance, such the determination of such length is independent from the determination of the length of the gate oxide 110, and therefore, typically, the length of the gate oxide 110 projectively over the first well region 102 is substantially different from the length of the thickened gate oxide 112 projectively over the second well region 104.

The material of the gate electrode 114 over the gate oxide 110 and the thickened gate oxide 112 may include aluminum, polysilicon, or the like. In some embodiments, the gate electrode 114 is a polysilicon gate that serves as the external terminal of the semiconductor structure 10 through which a voltage is applied.

As shown in FIG. 1, in some embodiments, the gate structure can be seen that features a two-tiered trapezoidal configuration, and the portion of the gate structure in proximity to the drain region is elevated due to the thickness of the thickened gate oxide 112. In other words, the thickness of the gate electrode 114 in each part of the gate structure is substantially the same. Furthermore, the thickness of the gate oxide material in proximity to the source region or above the standard position of the gate oxide cannot be increased. This is because a change in the thickness of the gate oxide would lead to a mismatch between the thicknesses of the gate oxide and the applied voltage. Accordingly, some embodiments of the present disclosure use the additional thick gate oxide combined with the original gate oxide of the semiconductor structure as an approach to optimize the on-resistance of the semiconductor structure. For instance, the on-resistance of the semiconductor structure can thus lower than about 1 mΩ/mm².

In some embodiments, the semiconductor structure further includes a plurality of gate spacers 116 cover the sidewalls of the gate structure. In some embodiments, the material of the gate spacers 116 may include silicon nitride (Si₃N₄) or silicon dioxide (SiO₂). The gate spacers 116 may providing electrical isolation and acting as a mask during certain fabrication processes (e.g., the forming of a N⁺ region 118 for a drain region 120 and the forming of another N⁺ region 122 and a P⁺ region 124 for a source region 126). Hence, in some embodiments, the second well region 104 is substantially and entirely covered by the gate electrode 114 at the first surface 100A of the substrate 100.

Still referring to FIG. 1, in some embodiments, the source region 126 is adjacent to a side of the gate electrode 114; and the drain region 120 is adjacent to another side of the gate electrode 114. In some embodiments, a gate contact should be positioned over the gate oxide 110 (i.e., the portion that the gate oxide remains unthickened), otherwise the aforementioned mismatch between the thicknesses of the gate oxide material and the applied voltage would occur.

In some embodiments, the semiconductor structure 10 further includes or connected with a circuit 128. The circuit 128 can be a driver IC or called gate driver IC, which is coupled to the gate structure, configured to provide a second voltage to the gate structure. In some embodiments, the second voltage is about 2.5V. In some embodiments, the semiconductor structure 10 further includes or connected with a voltage source 130 (e.g., a power supply). The voltage source 130 is coupled to the drain region 120, configured to provide a first voltage to the drain region 120. In some embodiments, the first voltage is in a range from about 5V to about 10V. Accordingly, a ratio of the first voltage (e.g., a drain voltage) of the semiconductor structure to the second voltage (e.g., a gate voltage) of the semiconductor structure is in a range from 2 to 4.

As mentioned earlier, the thickness of the gate oxide 110 in the gate structure is associated with the voltage applied to the gate structure. Given that some embodiments of the present disclosure include a 2.5V gate structure and the semiconductor structure's drain voltage falls within the range of approximately 5V to 10V, there is a need to bridge the voltage difference between them without compromising the semiconductor structure's performance. Therefore, some embodiments of the present disclosure introduce a gate structure in which the gate oxide extends towards the drain region, undergoing partial thickening.

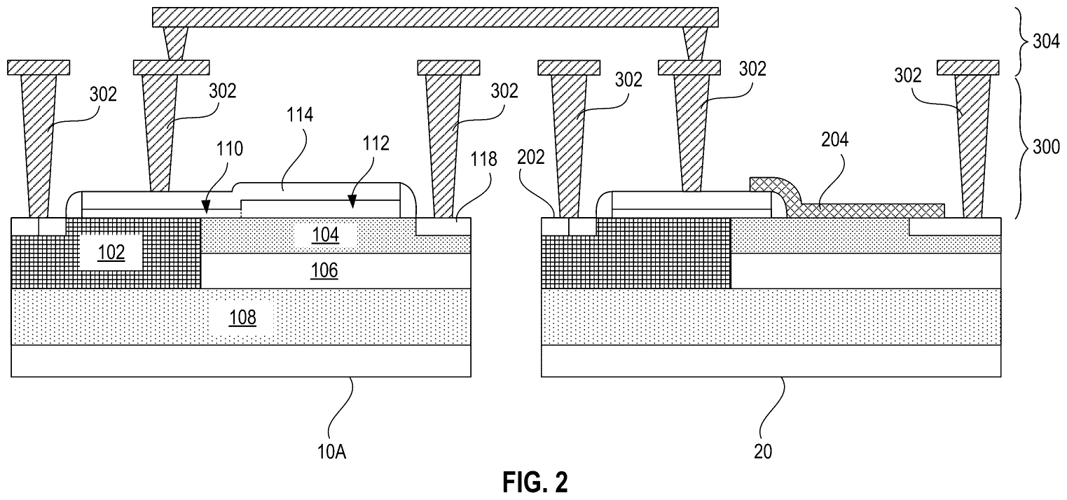

Referring to FIG. 2, in some embodiments, the semiconductor structure, which is a first transistor 10A having a ratio relationship between the gate voltage and the drain voltage, can be coupled to another transistor (e.g. a second transistor 20) that free from having a gate oxide including a thin portion and a thickened portion (i.e., a transistor having a resist protective oxide (RPO) layer 204 formed over a gate structure, a gate sidewall spacer structure, and a N-well region, along the profile of the gate structure, the gate sidewall spacer structure, and a substrate thereof). In such embodiments, each of the gate structure, drain region, and the source regions are in contact with a conductive contact 302 penetrating an ILD layer 300 over the first transistor 10A and the second transistor 20. These conductive contacts 302 are electrically connected to a metallization layer 304 over the ILD layer 300, and the metal layers and metal contacts in the metallization layer 304 may provide conductive path for coupling the first transistor 10A and the second transistor 20. For instance, the second transistor 20 may include a second source region 202 configured to provide a second voltage to the gate electrode 114 of the first transistor 10A. In some embodiments, the second transistor 20 is a part of gate driver or a circuit for controlling the first transistor 10A. In some embodiments, the second voltage is about 2.5V. Also, the drain region 118 of the first transistor 10A may be coupled to a voltage source (not shown in FIG. 2; see FIG. 1 for example) configured to provide a second voltage to the drain region 118 of the first transistor 10. In some embodiments, the second voltage is in a range from about 5V to about 10V.

In other words, the semiconductor structures in this disclosure are not intended for high voltage applications (e.g., greater than about 10V), but are suitable for applications where the gate voltage and the drain voltage differ and within a relatively low voltage range. Otherwise, the voltage endurance of the semiconductor structures would need to be further increased, potentially negating the advantage of the low on-resistance disclosed in the present disclosure.

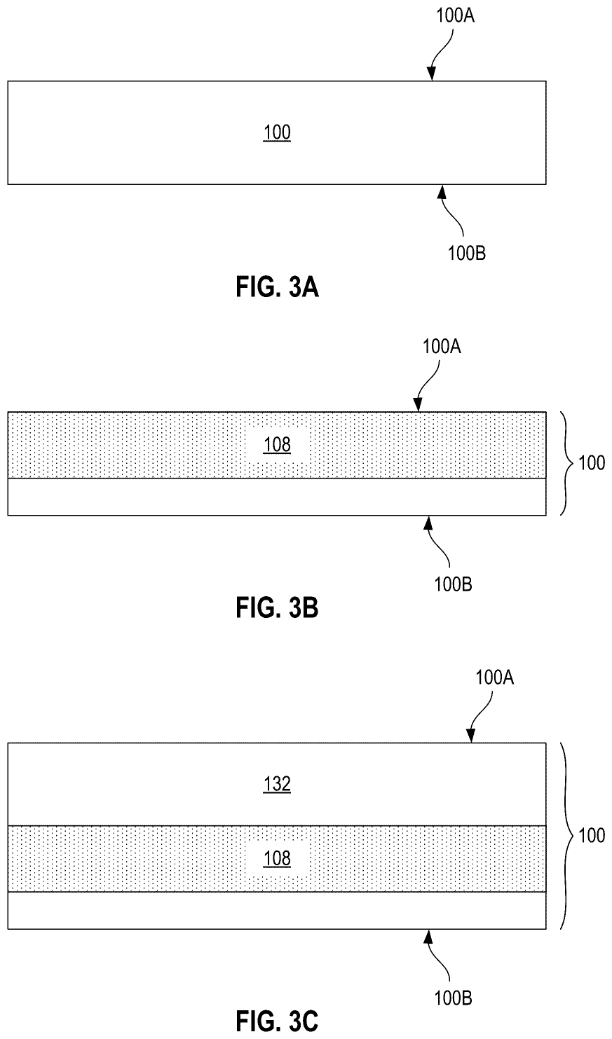

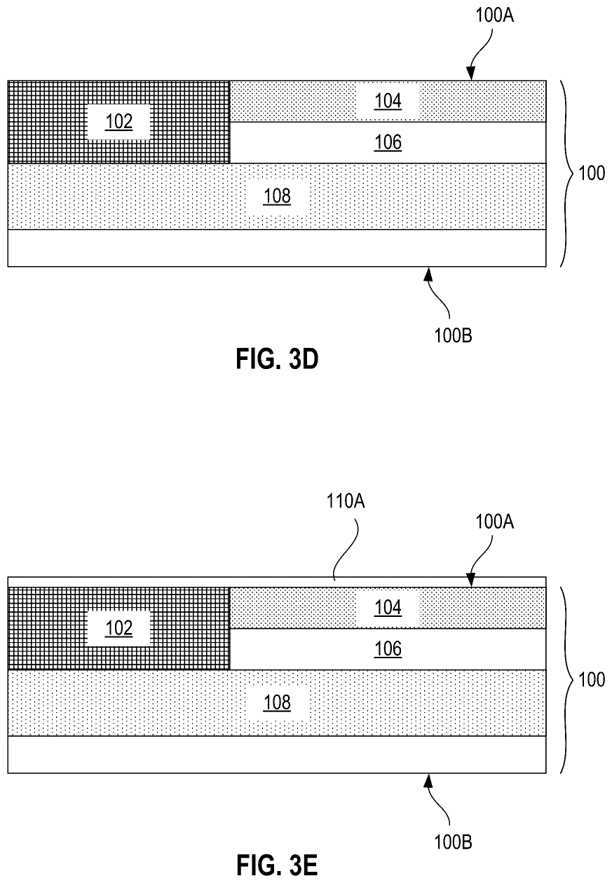

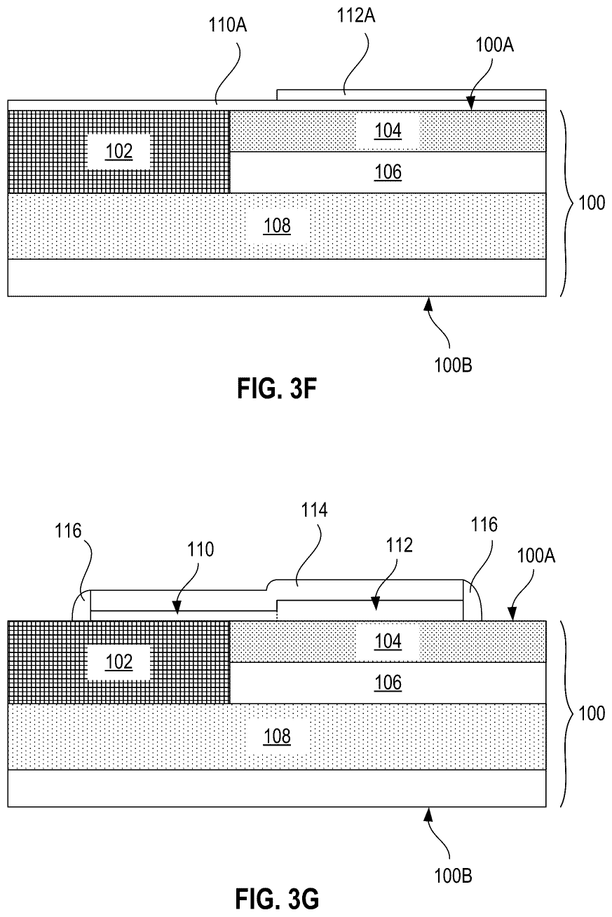

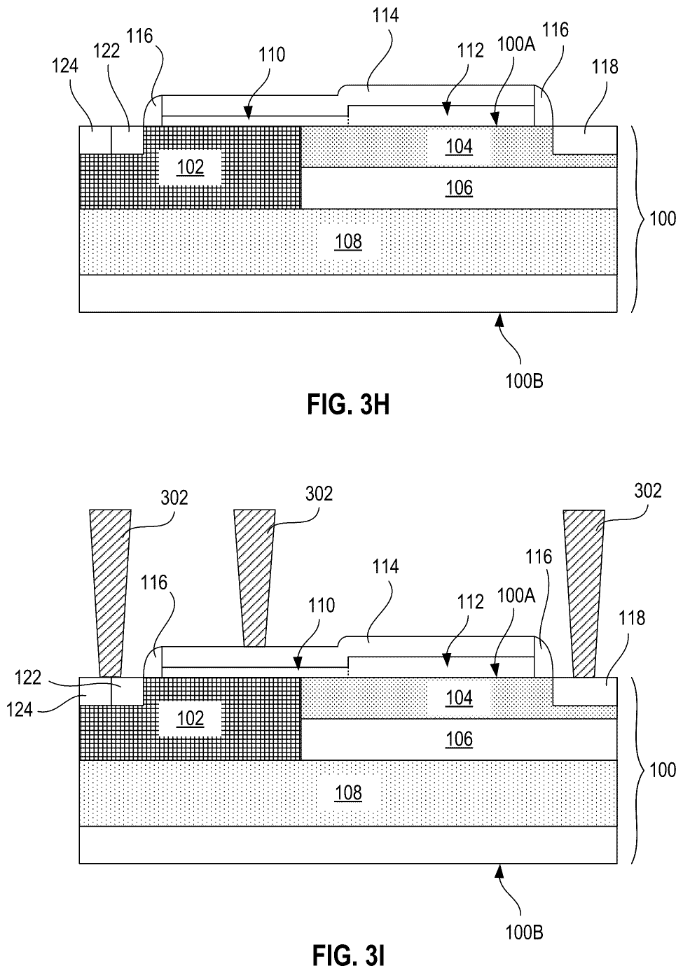

An example process to form the semiconductor structure having low on-resistance as shown in FIG. 1 can be seen in FIGS. 3A to 31. As shown in FIG. 3A, a substrate 100 having a first surface 100A and a second surface 100B opposite to the first surface 100A is received. In some embodiments, the substrate 100 may be a P-type wafer, such P-type wafer can be formed by using P-type dopants to confer P-type characteristics to a semiconductor wafer. In some embodiments, the resistivity of the substrate 100 is in a range from about 1 ohm-cm to about 100 ohm-cm.

Next, referring to FIG. 3B, in some embodiments, an N⁺ buried layer (NBL) 108 can be formed within the substrate 100. The NBL 108 can be formed by implementing an ion implantation operation to introduce an N-type dopant impurity into the substrate 100. As aforementioned, the NBL 108 can be constituted by the N-type dopant that is a heavy atom and resistant to diffusion during subsequent high-temperature processes. In some embodiments, the dopant impurity concentration of the NBL 108 is in a range from about 1×10¹⁴ atoms/cm² to about 1×10¹⁶ atoms/cm².

Referring to FIG. 3C, in some embodiments, a p-type epitaxial layer 132 can be formed subsequently by employing a P-type epitaxial deposition process. In some embodiments, the resistivity of the P-type epitaxial layer 132 is in a range from about 1 ohm-cm to about 100 ohm-cm. Until now, the substrate 100 has been changed from the P-type wafer into a stack of p-type substrate and p-type epitaxial layer, with the NBL 108 there between.

Referring to FIG. 3D, in some embodiments, the first well region 102 and the second well region 104 are formed in the p-type epitaxial layer 132 at the first surface 100A of the substrate 100. The forming of the well regions may employ the patterning operations (e.g., including the use of photolithography, mask, etc.) that involves selectively defining specific areas where dopant materials will be introduced, thereby creating regions with modified electrical properties. In some embodiments, the dopant impurity concentration of the first type dopant in the first well region 102 is in a range from about 1×10¹¹ atoms/cm² to about 9×10¹³ atoms/cm². In some embodiments, the dopant impurity concentration of the second type dopant in the second well region 104 is in a range from about 1×10¹¹ atoms/cm² to about 9×10¹³ atoms/cm². In some embodiments, the dopant impurity concentration of the P-type dopant in the deep P-well region 106 is in a range from about 1×10¹¹ atoms/cm² to about 9×10¹³ atoms/cm².

Referring to FIG. 3E, in some embodiments, a blanket depositing operation can be employed to deposit a first gate oxide material 110A over the first surface 100A of the substrate 100. The first gate oxide material 110A includes silicon dioxide (SiO₂). In some embodiments, the thickness of the first gate oxide material 110A is no greater than about 10 μm.

Subsequently, a mask layer (not shown in the figure) can be formed over the first gate oxide material 110A and expose a region of the first gate oxide material 110A, and then depositing a second gate oxide material 112A (see FIG. 3F) over the first gate oxide material 110A. In some embodiments, the material of the second gate oxide material 112A is identical to that of the first gate oxide material 110A. In some embodiments, the second gate oxide material 112A are entirely formed over the second well region 104 and the deep P-well region 106. In some embodiments, a total thickness of the second gate oxide material 112A and the first gate oxide material 110A directly below the second gate oxide material 112A is in a range from about 10 nm to about 100 nm.

Referring to FIG. 3G, in some embodiments, a gate electrode 114 can be formed over the stack of the first gate oxide material 110A and the second gate oxide material 112A (i.e., the gate oxide), and be patterned to have both sides thereof aligned with the two sides of the gate oxide there below. The material of the gate electrode 114 may include aluminum, polysilicon, or the like. Since the stack of the first gate oxide material 110A and the second gate oxide material 112A may induce a stepped profile from the cross-sectional perspective, the gate electrode 114 formed thereon may reproduce such stepped profile from the cross-sectional perspective. In some embodiments, a plurality of gate spacers 116 can be formed to laterally surround the gate oxide and the gate electrode 114. In some embodiments, each of the plurality of gate spacer 116 are in contact with the first surface 100A of the substrate 100 and are leveled with each other. In some embodiments, the material of the gate spacers 116 may include silicon nitride (Si₃N₄) or silicon dioxide (SiO₂).

Referring to FIG. 3H, the gate spacers 116 may providing electrical isolation and acting as a mask during certain fabrication processes. As shown in the figure, an N⁺ region 118 can be formed for a drain region 120 and another N⁺ region 122 and a P⁺ region 124 can be formed for a source region 126. The forming of these doped regions may employ the patterning operations (e.g., including the use of photolithography, mask, etc.) that involves selectively defining specific areas where dopant materials will be introduced, thereby creating regions with modified electrical properties.

Referring to FIG. 3I, in some embodiments, an ILD layer 300 can be formed over the first surface 100A of the substrate 100. The ILD layer 300 may include low-k material and formed through the PECVD technique. Next, a plurality of conductive contacts 302 can be formed in the ILD layer 300 and landing on the gate electrode 114, drain region 120, and source region 126 through the etching and metal filling operations. The metallization layer 304 (see FIG. 2 as examples) can be subsequently formed over the ILD layer 300. In some embodiments, as previously shown in FIG. 2, different transistor structures can be coupled other transistor structures through the metallization layer 304.

Overall, the present disclosure provides a semiconductor structure with a gate oxide that has a stepped profile from a cross-sectional perspective. This feature of the gate oxide may provide a benefit in optimizing on-resistance performance for low voltage applications. In some examples, the on-resistance can be greatly decreased to lower than 1 mΩ/mm², which is equivalent to about a 20% reduction in on-resistance. Furthermore, not only can the on-resistance be decreased, but it also allows for an increase in on-mode current and a decrease in the source-to-drain pitch at the same time.

In one exemplary aspect, a method for manufacturing a semiconductor structure is provided. The method includes the following operations. A substrate having a first surface and a second surface opposite to the first surface is received, wherein the substrate includes a first well region having a first-type dopant in proximity to the first surface of the substrate and a second well region having a second-type dopant in proximity to the first surface of the substrate and adjacent to the first well region. A gate oxide is formed over the first surface of the substrate, wherein the gate oxide comprises a stepped profile from a cross-sectional perspective. A gate electrode is formed over the gate oxide and the thickened gate oxide. A source region is formed in the substrate adjacent to a side of the gate electrode. A drain region is formed in the substrate adjacent to another side of the gate electrode. A ratio of a first voltage applied to the drain region to a second voltage applied to the gate electrode is in a range from 2 to 4.

In another exemplary aspect, a method for manufacturing a semiconductor structure is provided. The method includes the following operations. A substrate having a first surface and a second surface opposite to the first surface is received. A first transistor structure is formed on the first surface of the substrate. A first drain region of the first transistor structure is coupled to a voltage source configured to provide a first voltage to the first drain region of the first transistor structure. The first transistor structure is coupled to a second transistor structure, wherein the second transistor structure includes a second source region configured to provide a second voltage to a first gate electrode of the first transistor structure. A ratio of the first voltage to the second voltage is in a range from 2 to 4. Moreover, the forming of the first transistor structure on the first surface of the substrate includes the following operations. A gate oxide is formed over the first surface of the substrate, wherein the gate oxide includes a stepped profile from a cross-sectional perspective. A first source region is formed in the substrate adjacent to a side of the first gate electrode. The first drain region is formed in the substrate adjacent to another side of the first gate electrode.

In yet another exemplary aspect, a semiconductor structure is provided. The semiconductor structure includes a substrate, a plurality of well regions, a gate structure, a drain region, a source region, a circuit, and a voltage source. The substrate has a first surface and a second surface opposite to the first surface. The plurality of well regions are in the substrate. The gate structure is over the substrate. The gate structure includes a gate oxide over the first surface of the substrate and a gate electrode over the gate oxide. The gate oxide includes a first portion overlapping a boundary of two well regions in the substrate, and a second portion connected with the first portion, wherein a thickness of the second portion is greater than a thickness of the second portion. The drain region is in the substrate, wherein the second portion of the gate oxide of the gate structure is adjacent to the drain region. The source region is in the substrate. The voltage source is coupled to the drain region, configured to provide a first voltage to the drain region. The circuit is coupled to the gate structure, configured to provide a second voltage to the gate structure. A ratio of the first voltage to the second voltage is in a range from 2 to 4.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, the method comprising:
receiving a substrate having a first surface and a second surface opposite to the first surface, wherein the substrate comprises:
a first well region having a first type dopant in proximity to the first surface of the substrate; and
a second well region having a second type dopant in proximity to the first surface of the substrate and adjacent to the first well region;
forming a gate oxide over the first surface of the substrate, wherein the gate oxide comprises a stepped profile from a cross-sectional perspective;
forming a gate electrode over the gate oxide;
forming a source region in the substrate adjacent to a side of the gate electrode; and
forming a drain region in the substrate adjacent to another side of the gate electrode;
wherein a ratio of a first voltage applied to the drain region to a second voltage applied to the gate electrode is in a range from 2 to 4.

2. The method of claim 1, wherein the gate oxide comprises a thickened portion having a thickness in a range from about 10 nm to about 100 nm.

3. The method of claim 2, wherein the thickened portion of the gate oxide is free from covering the first well region.

4. The method of claim 2, wherein a length of the thickened portion of the gate oxide is in a range from about 0.03 μm to about 1 μm.

5. The method of claim 4, wherein a length of the gate oxide over the second well region is shorter than the length of the thickened portion of the gate oxide.

6. The method of claim 1, wherein the operations of forming the gate oxide comprises:
blanket depositing a first gate oxide material over the first surface of the substrate;
forming a mask layer over the first gate oxide material and expose a region of the first gate oxide material; and
depositing a second gate oxide material over the first gate oxide material.

7. The method of claim 1, further comprising:
forming an n-type buried layer (NBL) in a p-type substrate;
forming a p-type epitaxial layer over the NBL; and
forming the first well region and the second well region in the p-type epitaxial layer.

8. A method for manufacturing a semiconductor structure, the method comprising:
receiving a substrate having a first surface and a second surface opposite to the first surface;
forming a first transistor structure on the first surface of the substrate, comprising:
forming a gate oxide over the first surface of the substrate, wherein the gate oxide comprises a stepped profile from a cross-sectional perspective;
forming a first gate electrode over the gate oxide;
forming a first source region in the substrate adjacent to a side of the first gate electrode; and
forming a first drain region in the substrate adjacent to another side of the first gate electrode;
coupling the first drain region of the first transistor structure to a voltage source configured to provide a first voltage to the first drain region of the first transistor structure; and
coupling the first transistor structure to a second transistor structure, wherein the second transistor structure comprises a second source region configured to provide a second voltage to the first gate electrode of the first transistor structure,
wherein a ratio of the first voltage to the second voltage is in a range from 2 to 4.

9. The method of claim 8, wherein a second gate of the second transistor structure is free from having a gate oxide with a stepped profile from a cross-sectional perspective.

10. The method of claim 8, wherein the second voltage is in a range from about 5V to about 10V.

11. The method of claim 8, further comprising:
forming an ILD layer over the first surface of the substrate;
forming a gate contact and a drain contact landing on the first gate electrode and the first drain region, respectively; and
forming a metallization layer over the ILD layer, wherein the first transistor structure is coupled to the second transistor structure and the voltage source through the metallization layer.

12. The method of claim 8, further comprising:
determining a length of a thickened portion of the gate oxide between a thin portion of the gate oxide and the first drain region prior to forming the gate oxide and the first drain region to make the first transistor structure having an on-resistance lower than about 1 mΩ/mm².

13. The method of claim 8, wherein the first voltage is about 2.5V.

14. The method of claim 8, further comprising:
forming a plurality of gate spacers laterally surrounding the gate oxide and the gate electrode, wherein the plurality of gate spacer are leveled with each other.

15. A semiconductor structure, comprising:
a substrate having a first surface and a second surface opposite to the first surface;
a plurality of well regions in the substrate;
a gate structure over the substrate, comprising:
a gate oxide over the first surface of the substrate, comprising;
a first portion overlapping a boundary of two well regions in the substrate; and
a second portion connected with the first portion, wherein a thickness of the second portion is greater than a thickness of the second portion; and
a gate electrode over the gate oxide;
a drain region in the substrate, wherein the second portion of the gate oxide of the gate structure is adjacent to the drain region;
a source region in the substrate;
a voltage source coupled to the drain region, configured to provide a first voltage to the drain region; and
a circuit coupled to the gate structure, configured to provide a second voltage to the gate structure;
wherein a ratio of the first voltage to the second voltage is in a range from 2 to 4.

16. The semiconductor structure of claim 15, wherein a thickness of the first portion of the gate oxide is no greater than about 10 nm.

17. The semiconductor structure of claim 15, wherein a thickness of the second portion of the gate oxide is in a range from about 10 nm to about 100 nm.

18. The semiconductor structure of claim 15, wherein the plurality of well regions comprises:
a first well region having a first type dopant at the first surface of the substrate; and
a second well region having a second type dopant at the first surface of the substrate and adjacent to the first well region,
and wherein the second well region at the first surface of the substrate is entirely covered by the second portion of the gate oxide.

19. The semiconductor structure of claim 15, wherein a length of the second portion of the gate oxide is in a range from about 0.03 μm to about 1 μm.

20. The semiconductor structure of claim 15, wherein the length of the second portion of the gate oxide is different from a length of the first portion of the gate oxide.
